(19) United States
(12) Patent Application Publication
(10) Pub. No.: US 2010/0329287 A1
(43) Pub. Date: Dec. 30, 2010

(54) METHOD AND DEVICE FOR STABILIZING THE SPECTRUM OF A PULSED COHERENT OPTICAL SOURCE

(75) Inventor: Steve Lecomte, Bernex (CH)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: CSEM Centre Suisse d'Electronique et de Microtechnique S.A., Neuchatel (CH)

(21) Appl. No.: 12/918,956

(22) PCT Filed: Feb. 20, 2009
(86) PCT No.: PCT/CH2009/000073

§ 371 Date: Aug. 23, 2010

(30) Foreign Application Priority Data
Feb. 22, 2008 (EP) 08405059.0

(51) Int. Cl. H01S 3/13; H01S 3/30; H01S 5/0687; H01S 3/098

(52) U.S. Cl. 372/3; 372/32; 372/6; 372/18

(57) ABSTRACT

The invention relates to a method for stabilizing the spectrum of a pulsed coherent optical source that comprises controlling the offset frequency ω₀ and the repetition rate ωᵣ in order to stabilize the frequencies of the comb lines constituting the optical spectrum thereof. The method comprises forming, from the pulsed coherent optical source (S₁), a beam that is directed onto a reference resonant optical cavity (CR), and using the signal generated by the reference resonant optical cavity (CR) for controlling the offset frequency ωₒ or the repetition rate ωᵣ, and probing, using a comb line, an atomic or molecular transition (AMT) in order to generate a driving signal for the repetition rate ωᵣ or the offset frequency ω₀.

The present invention pertains to a method for stabilizing the spectrum of a pulsed coherent optical source according to which the offset frequency ω₀ and the repetition rate ωᵣ are slaved so as to slave the frequencies of the comb lines which make up its optical spectrum, as well as to a device for the implementation of this method.

Precise and stable oscillators are used in a good many applications. Miniaturization and reduction in the electrical consumption of such oscillators would be desirable in particular for portable or autonomous instruments.

A miniature clock based on microwave atomic transitions rather than on an optical transition has already been proposed in “The miniature atomic clock—pre-production results” R. Lutwak et al., Proceedings EFTF07. Choosing an optical transition makes it possible to increase the quality factor of the reference resonance and therefore the performance of the oscillator.

An optical clock requires the use of a mode-locked laser as a frequency divider to bring an optical frequency to a microwave frequency. This has been proposed by Prof. Theodore Hänsch of the University of Munich and of the Max Planck Institute of Garching in Germany and by Prof. John Hall of JILA, Boulder, Colo., USA. The Nobel prize for physics was awarded to them in 2005 for this invention. A new generation of atomic clocks based on optical transitions is currently under development and has already demonstrated superior performance to the best atomic clocks based on microwave transitions.

The frequency of each mode n of the optical spectrum emitted by a mode-locked pulsed laser is given by the following relation where n is an integer:

ω_{opt,n}=n.ωᵣ+ω₀

In an optical clock, a continuous laser or a mode of the pulsed laser is slaved to an optical transition. To be able to utilize the frequency stability obtained at the optical frequency, the mode-locked pulsed laser acts as a frequency divider. The repetition rate of the pulsed laser will possess the same relative frequency stability as the optical frequency and it can therefore be processed electronically and serve the user as a frequency reference. To divide the optical frequency in an exact manner, the offset frequency ω₀ must be known and stabilized. The stabilization of the offset frequency ω₀ is obtained by virtue of an f-2f non-linear interferometer such as shown diagrammatically in Th. Udem et al., Optical Frequency Metrology, Nature 416 233-237, 2003.

The frequency of the repetition rate is typically between 75 MHz and 2 GHz for the lasers customarily used in these applications. The principle which has just been described is precisely that of an optical atomic clock in which a continuous laser is slaved in a very stable manner to a reference atom or ion.

With the aim of manufacturing a miniature optical clock, the standard concept of stabilizing the pulsed laser with the f-2f non-linear interferometer does not seem very suitable for reasons of consumption and complexity. Indeed to produce an f-2f non-linear interferometer, an optical spectrum covering an octave is required. To generate this wide spectrum, short and energetic pulses arising from a bulky laser and requiring several watts to several tens of watts of power are currently necessary.

In order to circumvent the power constraint of the optical pulses for the non-linear interferometer, the stabilization of the offset frequency ω₀ is done on an ultrastable external cavity. R. J. Jones et al have already, in “Precision stabilization of femtosecond lasers to high finesse optical cavities” Phys. Rev. A 69, 051803(R) (2004), performed a detailed comparison of two stabilization systems which leads to a new understanding of the optimum conditions and the limits for the stabilization of a cavity on the capacity to transfer the frequency stability of the cavity to the microwave region. The stability of the frequency comb is explored both in the optical region and in the radio frequency region. The stabilization of the repetition rate can be done either also on an external cavity (therefore creating a non-referenced oscillator) or else on an atomic or molecular transition (atomic clock and therefore referenced oscillator).

In the case of R. J. Jones et al., the repetition rate is stabilized on the resonant cavity. The resonant cavity inevitably exhibits a drift of its resonant frequencies due to variations of its length (vibration and temperature essentially).

In R. J. Jones et al. mentioned above, the laser used is a laser of titanium-sapphire type and is therefore incompatible with electrical consumption of less than several watts. In order to obtain good frequency stability, the chosen laser produces short pulses of light (less than 20 femtoseconds). The reference cavity possesses a length of 39.5 cm and the propagation of the light beams is of free propagation type. This choice of components has been prompted by the desire to test the limits of the frequency stability of the laser repetition rate on an external cavity without worrying about other aspects such as consumption and compactness.

The aim of the present invention is to remedy, at least in part, the drawbacks of the abovementioned solutions.

For this purpose, the subject of the invention is a method for stabilizing the spectrum of a pulsed coherent optical source according to claim 1 or according to claim 2. Its subject is also a device for the implementation of the method according to claim 1 such as defined by claim 6 and a device for the implementation of the method according to claim 2 such as defined by claim 7.

The essential difference between the scheme of Jones et al. and the present invention resides essentially in the medium-term and long-term stability of the microwave frequency generated by the device. In the case of the present invention, the repetition rate is stabilized on an atomic or molecular reference which intrinsically offers greater environmental stability.

The inventive concept adopted here furthermore makes it possible to address the requirements of miniaturization and of significant limitation of consumption which, together with the sought-after precision, constituted two additional objectives of the present invention, making it possible to marshal the conditions necessary for the production of a low-power portable device.

Featuring among the key elements of the invention is the combination of a low-consumption compact pulsed laser whose pulses are not necessarily ultrashort with a compact and ultrastable reference cavity. According to the proposed embodiments, a reference transition interrogated directly with the pulsed laser or indirectly by means of a slaved continuous laser can also be used.

Advantageously, this device could be fiber-based or produced using integrated optics together with other types of waveguides. Currently such systems are bulky, they consume a great deal of energy and they call upon technologies which are incompatible with miniaturization of the device. For each physical sub-system, a list of relevant components for achieving the consumption and compactness objectives is proposed. It is clear that any combination of these sub-systems is possible in order to achieve the consumption and compactness aims.

The term physical sub-systems includes the elements such as the laser, the waveguides, the reference cavity, the atomic reference, the photodetectors, the lenses, the phase modulators, the optical filters, etc. The elements of the device which do not form part of the physical sub-systems are: the power supply electronics and the control and stabilization electronics.

The compact and ultrastable resonant optical cavity is used at least for the stabilization of the offset frequency of the optical spectrum of the pulsed light source. Various types of cavity are envisaged:

1. A solid gauge made of ultra-low expansion rate glass so as to minimize the thermal drifts which cause a variation of its length. Dielectric mirrors of very high reflectivity are fabricated on its faces so as to obtain a high finesse (or quality factor) of the resonator making it possible to raise the performance of the device. Such gauges are described on the site www.generaloptics.com.

2. A gauge such as described above, but with hollow air-filled or evacuated cavity so as to limit the thermal drifts of the gauge (variation of its length) because of residual absorption of the light stored in the resonator causes heating. The hollow cavity also offers the advantage of eliminating the dispersion due to the glass of the gauge mentioned in point 1. There is information relating to this gauge on the site mentioned in point 1.

3. An ultracompact resonator of annular type with high quality factor described in EP 1554618 B1.

4. An ultracompact optical resonator based on a mechanically structured material and based on the photonic bandgap effect (P. Pottier et al., Triangular and Hexagonal High Q-Factor 2-D Photonic Bandgap Cavities on III-V Suspended Membranes, J. Lightwave Technology, 17 2058 (1999)).

The pulsed coherent optical source is compact and has low consumption. It acts as a frequency divider from the optical region to the microwave region. The stable and pure microwave frequency produced by the complete arrangement is provided by the repetition rate of the stabilized pulsed optical source. With the aim of obtaining a low-consumption compact device, the following sources are possible:

1. Laser of edge-emitting quantum well multi-section type with saturable absorber DE 10322112 B4.

2. Laser of edge-emitting quantum dot multi-section type with saturable absorber, Y. -C. Xin et al., Reconfigurable quantum dot monolithic multi-section passive mode-locked laser, Optics Express 15 7623 (2007).

3. Vertical-cavity surface-emitting laser (VECSEL) with saturable absorber not integrated into the structure generating the optical gain, D. Lorenser et al., Toward wafer-scale integration of high repetition rate passively mode-locked surface emitting semiconductor lasers, Appl. Phys. B 79 927 (2004).

4. External-cavity surface-emitting mode-locked integrated laser (MIXSEL), A. R. Bellancourt et al., First demonstration of a modelocked integrated external-cavity surface emitting laser (MIXSEL), CLEO 07, talk CWI1.

5. Fiber laser J. Chen et al., High repetition rate, low jitter, low intensity noise, fundamentally mode-locked 167 fs soliton Er-fiber laser, 32 1566 (2007).

6. Laser of Raman type, B. R: Koch et al., Mode-locked silicon evanescent lasers, Opt. Express 15 11225 (2007).

7. Diode-pumped solid-state type laser with modes locked by a saturable absorbent based on a semiconductor (SESAM) L. Krainer et al., Compact Nd:YVO₄ lasers with pulse repetition rates up to 160 GHz, IEEE J. Quantum Electr. 38 1331 (2002).

8. Microtoroid resonator pumped by continuous light, US 2008285606 A1.

9. Optical-fiber resonator pumped by continuous light, T. Braje et al. (http://tf.nist.gov/cgi-bin/showpubs.p1).

In the proposed arrangements, one or more elements making it possible to spatially split various colors of the spectrum are required. Here is a non-exhaustive list of compact components compatible with the integrated optics approach able to deal with this task (non-exhaustive list):

1. Planar selective grating (AWG), www.jdsu.com.

2. Interleaver, www.jdsu.com.

3. Glass plate with dielectric coating whose reflectivity varies as a function of wavelength.

4. Diffraction grating.

5. Low-finesse resonant optical cavity with wide free spectral region.

In certain proposed arrangements, a phase modulator is required so as to carry out a slaving of Pound-Drever-Hall type, R. W. P. Dreyer et al., Laser phase and frequency stabilization using an optical resonator, Appl. Phys. B 31 97 (1983). In order to have a compact arrangement, the following manufacturers' phase modulators may be used (non-exhaustive list):

1. IBM, W. M. J. Green et al., Ultra-compact low RF power, 10 Gb/s silicon Mach-Zehnder modulator, Opt. Exp.15 17106 (2007)

2. Intel www.intel.com

3. JDSU www.jdsu.com

To ensure the compactness of all the arrangements described, waveguides of optical fiber type or channel waveguides (made of various materials such as silicon oxide, silicon nitride, silicon, polymers, etc.) (Book on the domain: http://www.crcpress.com/shoppingcart/products/productdetail.asp?sku=DK3157) may be used. The technologies associated with channel waveguides also make it possible to produce an optical microchip.

These waveguides also make it possible to ensure the coupling and decoupling of the laser beam of the various constituent elements of the arrangements.

One of the features of this invention is the ability to circumvent a very wide optical spectrum required (typically an octave) to be able to slave in a customary manner the offset frequency of the pulsed light source. Nonetheless a non-linear optical element allowing spectral widening makes it possible to improve the performance of the system. Indeed according to R. J. Jones et al. mentioned above, the quality of the stabilization of the offset frequency, therefore the stability of the repetition rate ωᵣ, increases with the spectral width used in accordance with the relation:

ω_{center}/(2π·Δf)

Where ω_{center} is the central frequency of the optical frequency interval Δf considered (Δf=ω_{b}−ωₐ) in the proposed arrangements.

In order to increase the spectral width of the source (without however attaining an octave), the use of an optically non-linear element is required. This element must be placed directly after the pulsed light source so as to benefit from the maximum of power of the pulses and therefore to widen the spectrum to the maximum. Various types of non-linear elements are possible and compatible with light-guiding technologies such as optical fiber or channel waveguide:

1. Highly non-linear optical fiber of standard single-mode type www.ofs.com or of photonic crystal type http://www.crystal-fibre.com/.

2. Waveguide with a geometry of conical type.

Note that the non-linear element has not been represented in the appended diagrams.

The continuous laser stabilized on an atomic or molecular optical reference must be of narrow spectral width. In the arrangements where such a laser is required, the microwave signal generated by the device will be designed to have the following effects:

1. The spectral width of the continuous laser will have an effect on the spectral purity of the microwave signal generated by the device (phase noise).

2. The medium-term and long-term frequency stability will have an effect on the medium-term and long-term frequency stability of the microwave source.

Such a laser may be produced with the following technologies:

1. Semiconductor laser of DFB type with distributed feedback or DBR laser with distributed Bragg reflector.

2. Semiconductor laser of Fabry-Pérot type with extended cavity.

3. Laser of toroidal resonator type L. Yang et al., A 4-Hz fundamental linewidth on-chip microlaser, CLEO 07, talk CMR2.

4. Fiber laser www.np-photonics.com.

The appended drawings illustrate, schematically and by way of example, four embodiments of devices for the implementation of the methods constituting the subject of the present invention.

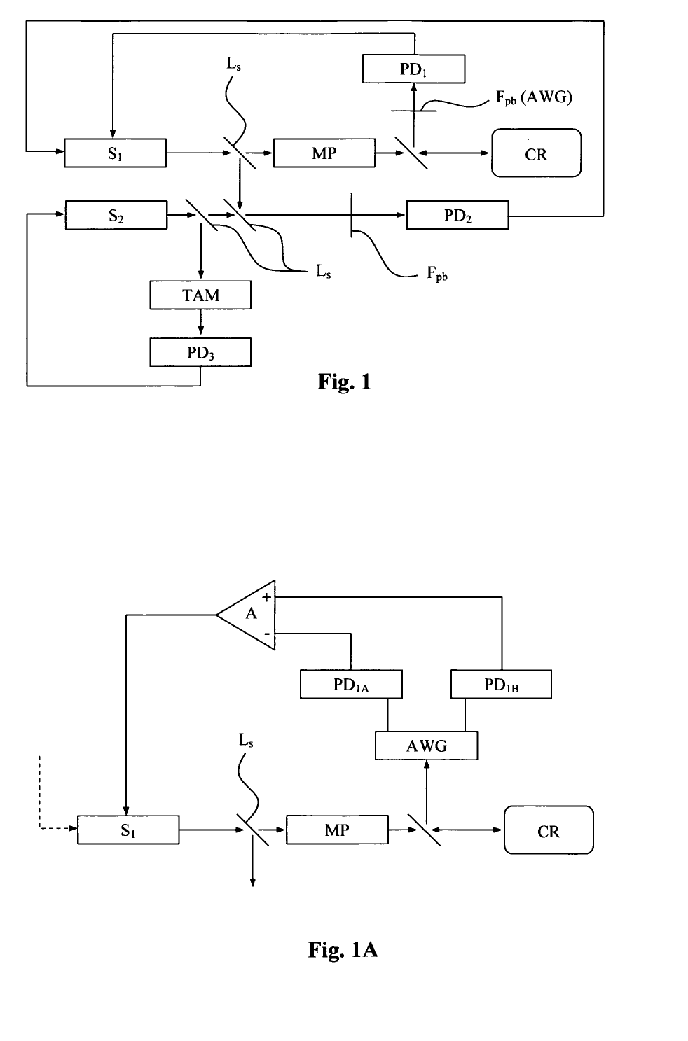

FIG. 1 is a basic diagram of a first embodiment;

FIG. 1A is a partial view of a variant of the diagram of FIG. 1;

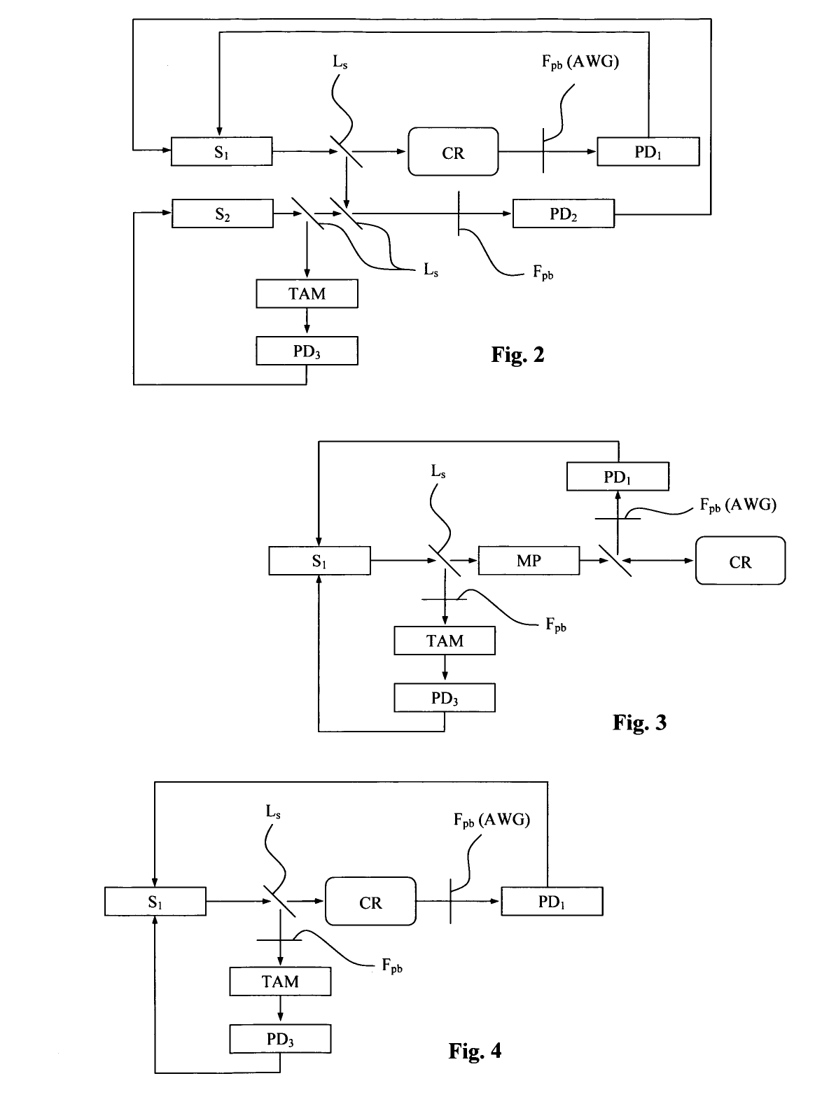

FIG. 2 is a basic diagram of a second embodiment;

FIG. 3 is a basic diagram of a third embodiment;

FIG. 4 is a basic diagram of a fourth embodiment.

The basic diagram of FIG. 1 comprises a pulsed coherent optical light source S₁ at the output of which is situated a splitter plate Lₛ or an element of interferential filter type or a Fabry-Pérot resonator, or an interleaver for spectral splitting. The splitter plate Lₛ directs the light of the source S₁ onto a phase modulator MP at the output of which a second splitter plate Lₛ directs the light toward a reference cavity CR so as to stabilize the offset frequency ω₀ or the repetition rate ωᵣ of the optical source S₁ by the Pound-Drever-Hall procedure. The optical signal arising from the reference cavity CR is directed by the second splitter plate toward a photodetector PD₁ through an optional bandpass filter F_{pb} so as to stabilize ωᵣ (FIG. 1) or toward two photodetectors PD_{1A} and PD_{1B} through a planar selective grating AWG so as to stabilize ω₀ as illustrated by FIG. 1A. The electrical signals arising from PD_{1A} and PD_{1B} are subtracted by a differential amplifier A and their difference is used as error signal to act on the optical source S₁ and stabilize the offset frequency ω₀. In the case where there is just a single photodetector PD₁, the electrical signal is referred to the optical source S₁ to stabilize the repetition rate ωᵣ thereof.

A second continuous coherent optical light source S₂ forms a continuous beam directed onto an atomic or molecular transition TAM, the signal of which is used to slave the continuous coherent optical source S₂. The frequency difference between a mode of the spectrum of the pulsed optical beam arising from the pulsed optical source S₁ and the continuous beam arising from the continuous optical source S₂ is moreover detected so as to slave the repetition rate ωᵣ or the offset frequency ω₀.

For this purpose, two splitter plates Lₛ are placed at the output of the optical source S₂. Advantageously a bandpass filter F_{pb} is placed in front of a photodetector PD₂ whose output is linked to the pulsed optical source S₁. The electrical signal exiting the photodetector serves to slave ωᵣ or ω₀.

The output of the atomic or molecular transition is directed onto a photodetector PD₃ whose electrical signal is transmitted to the continuous optical source S₂ so as to slave the optical frequency.

The embodiment illustrated by the diagram of FIG. 2 differs from that of the diagram of FIG. 1 essentially by the fact that the reference cavity CR slaves the offset frequency ω₀ or the repetition rate ωᵣ by the intensity of the luminous signal transmitted by the reference cavity CR, as shown by the diagram, or the photodetector PD₁ is situated at the output of the reference cavity CR, unlike in FIG. 1. Advantageously, a bandpass filter F_{pb} or a planar selective grating AWG or an interleaver is disposed between the reference cavity and the photodetector PD₁. In the case where a planar selective grating AWG is used, the variant of the partial diagram of FIG. 1A is applied to the processing of the luminous signal transmitted by the reference cavity CR of FIG. 2.

The remainder of the device of FIG. 2 is in every respect similar to that of FIG. 1 and reference may be made to the corresponding description of FIG. 1 which applies to FIG. 2.

The diagram of FIG. 3 is very much akin to that of FIG. 1, but in this case, only the pulsed coherent optical light source S₁ is used. As in the case of FIG. 1, the optical signal arising from the reference cavity CR is directed by the second splitter plate toward a photodetector PD₁ through an optional bandpass filter F_{pb} so as to stabilize the repetition rate ωᵣ by the Pound-Drever-Hall procedure or, as illustrated by the variant of FIG. 1A, toward two photodetectors PD_{1A} and PD_{1B} through a planar selective grating AWG so as to stabilize ω₀. The splitter plate Lₛ, which may be an element of interferential filter type or a Fabry-Pérot resonator or an interleaver, situated at the output of the pulsed optical source S₁, directs and selects a comb line of the optical spectrum on the bandpass filter F_{pb} situated between the splitter plate Lₛ and the atomic or molecular transition TAM. The comb line probes the atomic or molecular transition and the electrical absorption signal arising from the photodetector PD₃ makes it possible to slave the repetition rate ωᵣ or the offset frequency ω₀ of the source S₁.

The diagram of FIG. 4 is very similar to that of FIG. 2 and differs therefrom essentially only by the fact that it uses a pulsed light source S₁ only. As in the case of FIG. 2, the intensity transmitted by the reference cavity CR is directed toward a photodetector PD₁ through an optional bandpass filter F_{pb} so as to stabilize ωᵣ or, as illustrated by the variant of FIG. 1A, toward two photodetectors PD_{1A} and PD_{1B} through a planar selective grating AWG so as to stabilize ω₀. As in the case of FIG. 3, the splitter plate Lₛ, which may be an element of interferential filter type or a Fabry-Pérot resonator or an interleaver, situated at the output of the pulsed optical source S₁, directs and selects a comb line of the optical spectrum on the bandpass filter F_{pb} situated between the splitter plate Lₛ and the atomic or molecular transition TAM. The comb line probes the atomic or molecular transition and the electrical absorption signal arising from the photodetector PD₃ makes it possible to slave the repetition rate ωᵣ or the offset frequency ω₀ of the source S₁.

As regards the technical characteristics of the components used in the diagrams of FIGS. 1 to 4, the following values may be given by way of example:

In the case of a glass monolithic reference cavity CR, the highly reflecting dielectric treatment of the mirrors is carried out so as to obtain a reflectivity >99%. Preferably the treatment is performed with compensation of the dispersion of the glass. The length of the cavity is between 100 mm and 1.0 mm, corresponding to a free spectral region between 1 and 100 GHz respectively. The glass is of ultra low expansion (ULE) type.

In the case of the reference cavity CR with air vacuum and wedge, the glass is also of ultra low expansion (ULE) type. The mirrors are treated so as to have a reflectivity >99%, if possible the treatment is intended to have a zero dispersion over 100-200 nm, for a wavelength of 1550 nm and a length of between 150 mm and 1.5 mm corresponding to a free spectral region between 1 and 100 GHz respectively.

For the compact and low-consumption pulsed light source, depending on the type of laser, the wavelength lies between 750 nm and 1600 nm. The duration of the pulses lies between 100 fs and 10 ps. The spectral width of the pulses is between 0.25 nm and 25 nm for a wavelength of 1550 nm. The mean optical power is from 1 to 100 mW, the repetition rate is between 1 and 100 GHz. The consumption is 10 mW<300 mW<1000 mW.

For the microtoroid resonator pumped by continuous light, the wavelength is 1550 nm, the spectral width from 10 to 300 nm, the optical power is 10 mW<150 mW <200 mW, free spectral region lying between 10 GHz and 1000 GHz. The consumption is 30 mW<150 mW<600 mW.

The compact element making it possible to carry out the spatial splitting of the various spectral components is a planar selective grating (AWG), or an interleaver whose free spectral region lies between 50 and 100 GHz.

The atomic or molecular cell and reference referred to above as the atomic or molecular transition contains the reference in gaseous form. It may be a quartz or pyrex cell of dimension typically between 5 and 10 mm in length in the direction of propagation of the laser beam and between 5 and 10 mm in diameter.

It may also be a cell of MEMS type with silicon or pyrex substrate and two welded pyrex windows on either side of the substrate. A hole typically of 1 mm is made at the center of the substrate of 1 to a few mm in thickness defining the length of the optical path. The lateral dimension of the cell is from 2 to 5 mm along one side.

It may further be a microstructured hollow optical fiber cell. A reference gas is imprisoned in the core of the hollow fiber (diameter of the core <20 μm). The length of the fiber is between 10 and 1000 mm.

The reference atom or molecule is either an alkaline vapor, typically of rubidium or of caesium, or an acetylene gas, of hydrogen cyanide, of iodine (I₂), of water vapor, notably.

As regards the continuous coherent optical source, this is a laser of consumption 10<50<200 mW, of optical power 3<15<80 mW, of spectral width <1 MHz and whose wavelength as a function of the atomic or molecular reference lies between 750 and 1600 nm.

In the diagrams of FIGS. 1 to 4, the propagation of the beams may be either in optical fibers, or in waveguides so as to further limit the dimensions. Finally, to reduce the dimensions to the maximum, all these elements may be produced using integrated optics.

A volume and consumption balance sheet has been drawn up as regards the diagram of FIG. 1. A comparison has been carried out between the volume and the consumption of this device and a device of the prior art, in this instance that of R. J. Jones et al. mentioned above which constitutes the closest prior art.

The chosen dimensions of the components of FIG. 1 are as follows:

Pulsed laser S₁: length 1 mm, Ø 0.5 mm

Continuous laser S₂: length 1 mm, Ø 0.5 mm

Phase modulator MP: length 1 mm, Ø 1 mm

Planar selective grating AWG: 6 ×6 mm

Resonant cavity CR: 10 mm, Ø 3 mm

Photodetectors PD: 0.5 mm, Ø 0.5 mm Atomic/molecular transition cell TAM: 1×1 mm

TABLE 1
Volume/consumption balance sheet for the Jones et al. device.

| | | Femtosecond | | | | | |
|---|---|---|---|---|---|---|---|
| | Pump | titanium- | | | | | |
| Components | laser* | sapphire laser | AOM* | EOM* | Cavity | 3PD* | Total |
| Volume in cm³ | 5000 | 5000 | 20 | 80 | 200 | 0.125 | 10400 |
| Consumption | 30 | — | 1 | 1 | — | — | 32 |
| in Watts | | | | | | | |

*Voltage and current source not included.

TABLE 2
Volume/consumption balance sheet for the diagram of FIG. 1.

| | Pulsed | Continuous | | | | | | |
|---|---|---|---|---|---|---|---|---|
| Components | laser* | laser* | Cavity | EOM* | AWG | TAM | 4PD* | Total |
| Volume in cm³ | 2.5* × 10⁻⁴ | 2.5* × 10⁻⁴ | 0.09 | 5* × 10⁻⁴ | 0.036 | 10⁻³ | 5* × 10⁻⁴ | 0.13 |
| Consumption | 0.3 | 0.1 | — | 10⁻⁶ | — | | — | 0.4 |
| in Watts | | | | | | | | |

*Voltage or current source not included.

The volume and consumption values do not take account of the control and power supply electronics necessary for the device. The numbers give an achievable lower limit.

A reduction in the volume by a factor of 100′000 and a reduction in the consumption by a factor of 100 is noted with elements and technologies available to date.

1. A method for stabilizing the spectrum of a pulsed coherent optical source according to which the offset frequency ω₀ and the repetition rate ωᵣ are slaved so as to slave the frequencies of the comb lines which make up its optical spectrum, characterized in that a beam that is directed onto a reference resonant optical cavity is formed on the basis of the pulsed coherent optical source and the signal formed by the reference resonant optical cavity is used to slave the offset frequency ω₀ or the repetition rate ωᵣ and an atomic or molecular transition is probed by means of a comb line so as to form a signal for slaving the repetition rate ωᵣ or the offset frequency ω₀.

2. A method for stabilizing the spectrum of a pulsed coherent optical source according to which the offset frequency ω₀ and the repetition rate ωᵣ are slaved so as to slave the frequencies of the comb lines which make up its optical spectrum, characterized in that a pulsed beam that is directed onto a reference resonant optical cavity is formed on the basis of the pulsed coherent optical source and the signal formed by the reference resonant cavity is used to slave the offset frequency ω₀ or the repetition rate ωᵣ and a continuous coherent optical source is used to form a continuous beam that is directed onto an atomic or molecular transition, the signal from which is used to slave the continuous coherent optical source and the difference in frequency between the pulsed and continuous optical beams is detected so as to slave the repetition rate ωᵣ or the offset frequency ω₀.

3. The method as claimed in claim 1 according to which various colors of the spectrum of the optical comb are spatially split.

4. The method as claimed in claim 1, according to which the frequency of the optical region of the pulsed coherent optical source at the microwave region is divided by the repetition rate ωᵣ of the stabilized pulsed coherent optical source.

5. The method as claimed in claim 1, according to which the offset frequency ω₀ or the repetition rate ωᵣ is stabilized with the aid of a phase modulator by a slaving of Pound-Drever-Hall type.

6. A device for the implementation of the method as claimed in claim 1, comprising a pulsed coherent light source (S₁) of volume less than 10.10⁻⁴ cm³ and of power less than 1 W and an ultrastable reference resonant cavity (CR) of volume less than 0.2 cm³.

7. A device for the implementation of the method as claimed in claim 2, comprising a pulsed coherent light source (S₁) of volume less than 10.10⁻⁴ cm³ and of power less than 1 W, an ultrastable reference resonant cavity (CR) of volume less than 0.2 cm³ and a continuous coherent light source (S₂) of volume less than 10.10⁻⁴ cm³ and of a power less than 0.5 W.

8. The device as claimed in claim 6, comprising at least one optical element (Lₛ) for splitting various colors of the optical spectrum of the pulsed coherent optical source (S₁).

9. The device as claimed in claim 8 in which the optical element (Lₛ) for splitting various colors of the optical spectrum of the pulsed coherent optical source (S₁) is chosen from among the following elements: planar selective grating, interleaver, glass plate with dielectric coating whose reflectivity varies as a function of wavelength, diffraction grating, low-finesse resonant optical cavity with wide free spectral region.

10. The device as claimed in claim 6, in which the pulsed coherent light source (S₁) is chosen from among the following sources: edge-emitting quantum well multi-section laser with saturable absorber, edge-emitting quantum dot multi-section laser with saturable absorber, vertical-cavity surface-emitting laser (VECSEL) with saturable absorber not integrated into the structure generating the optical gain, an external-cavity surface-emitting mode-locked integrated laser (MIXSEL), a fiber laser, a Raman laser, a solid-state laser with mode locked by a saturable absorbent based on a semiconductor (SESAM), a microtoroid resonator pumped by continuous light, an optical-fiber resonator pumped by continuous light.

11. The device as claimed in claim 6, in which the ultrastable reference resonant cavity (CR) is chosen from among the following elements: monolithic glass gauge with ultra low expansion of ULE type whose faces comprise dielectric mirrors with reflectivity greater than 99%, the same glass gauge but with a hollow cavity, an ultracompact resonator of annular type with quality factor greater than 10⁶, an ultracompact optical resonator made of a mechanically structured material and based on the photonic bandgap effect.

12. The device as claimed in claim 6, in which the various elements of which it is composed are linked by optical-fiber waveguides or channel waveguides made of materials chosen from among the following materials: silicon oxide, silicon nitride, silicon, polymers or equivalents, so as to ensure the coupling and the decoupling of the laser beam between these various elements.

13. The device as claimed in claim 6, in which an optically non-linear spectral widening element is placed directly at the output of the pulsed coherent optical source, this spectral widening element being chosen from among the following components: highly non-linear optical fiber of standard single-mode type or of photonic crystal type, waveguide with a geometry of conical type.

14. The device as claimed in claim 7, in which the spectral width of the continuous coherent optical source (S₂) is less than 1 MHz and is formed by one of the following lasers: semiconductor laser of DFB type with distributed feedback or DBR laser with distributed Bragg reflector, semiconductor laser of Fabry-Pérot type with extended cavity, laser of toroidal resonator type, fiber laser.

15. The device as claimed in claim 6, in which at least a part of the optical components is made using integrated optics.

16. The method as claimed in claim 2, according to which various colors of the spectrum of the optical comb are spatially split.

17. The method as claimed in claim 2, according to which the frequency of the optical region of the pulsed coherent optical source at the microwave region is divided by the repetition rate ωᵣ of the stabilized pulsed coherent optical source.

18. The method as claimed in claim 2, according to which the offset frequency ω₀ or the repetition rate ωᵣ is stabilized with the aid of a phase modulator by a slaving of Pound-Drever-Hall type.

19. The device as claimed in claim 7, comprising at least one optical element (Lₛ) for splitting various colors of the optical spectrum of the pulsed coherent optical source (S₁).

20. The device as claimed in claim 7, in which the pulsed coherent light source (S₁) is chosen from among the following sources: edge-emitting quantum well multi-section laser with saturable absorber, edge-emitting quantum dot multi-section laser with saturable absorber, vertical-cavity surface-emitting laser (VECSEL) with saturable absorber not integrated into the structure generating the optical gain, an external-cavity surface-emitting mode-locked integrated laser (MIXSEL), a fiber laser, a Raman laser, a solid-state laser with mode locked by a saturable absorbent based on a semiconductor (SESAM), a microtoroid resonator pumped by continuous light, an optical-fiber resonator pumped by continuous light.
